(19) United States
(12) Patent Application Publication
(10) Pub. No.: US 2011/0226322 A1
(43) Pub. Date: Sep. 22, 2011

(54) SOLAR BATTERY UNIT

(75) Inventors: Kang-Chuang Lee, Taipei (TW); Chih-Kung Lee, Taipei (TW); Wen-Jong Wu, Taipei (TW); Min-Hua Yang, Taipei (TW); Pin-Han Kuo, Taipei (TW)

(73) Assignee: NATIONAL TAIWAN UNIVERSITY, Taipei (TW)

(21) Appl. No.: 12/840,179

(22) Filed: Jul. 20, 2010

(30) Foreign Application Priority Data
Mar. 22, 2010 (TW) 99108289

(51) Int. Cl. H01L 31/0216; H01L 31/0224; H01L 31/0236

(52) U.S. Cl. 136/256; 438/71; 257/E31.13

(57) ABSTRACT

A solar battery unit is proposed, including: a first electrode; a nano rough layer formed on the first electrode; a semiconductor active layer formed on the nano rough layer; and a second electrode formed on the semiconductor active layer, thereby enabling the nano rough layer formed on the first electrode to fully absorb solar energy not completely absorbed by the semiconductor active layer so as to allow solar energy to be fed back to the semiconductor active layer with a view to maximizing absorption of solar energy.

### BACKGROUND OF THE INVENTION

1. Field of the Invention

The present invention relates to solar energy elements, and more particularly, to a solar battery unit.

2. Description of the Prior Art

At present, organic semiconductor materials, of which solar energy devices are fabricated, are flexible, lightweight, thin, cheap to manufacture, and environmentally friendly. Organic semiconductors have lower carrier (electrons and holes) mobility rate than inorganic semiconductors and thus their electrons and holes have an extremely short drift distance, that is, less than 100 nanometers. Given a drift distance of greater than 100 nanometers, recombination of electrons and holes occurs readily to thereby cause a waste of absorbed solar energy. Although it is necessary for a solar energy device to be thin, but the solar energy device may be too thin to take in solar energy thoroughly.

According to the prior art, to prevent recombination of electrons and holes, it is necessary to use nanocarbon tubes or form holes by laser, and then fill the holes with an electron- or hole-conveying material so as to lower the chance of recombination of electrons and holes. However, the prior art of forming the aforesaid holes is limited by difficulty in controllably attaining nanoscale size and depth of the aforesaid holes and difficulty in forming deep said holes so as to prevent organic materials from being filled therein.

To increase the amount of solar energy taken in, that is, light absorption efficiency, it is necessary to use a metal plated film as a reflection layer and use a periodic grating so as to increase the rate of utilization of incident light by organic materials. However, in a laboratory setting, a metal membrane functioning as a reflection layer has a much lower rate of utilization of incident light than metallic nanoparticles functioning as a rough electrode surface. Also, there are plenty of restrictions on a periodic grating; for example, incident light requires a specific incident angle or polarization direction, otherwise absorption of light energy is rarely efficient.

Hence, it is imperative to solve the problems facing the prior art.

### SUMMARY OF THE INVENTION

In light of the aforesaid drawbacks of the prior art, it is an objective of the present invention to provide a solar battery unit, comprising: a first electrode; a nano rough layer disposed on the first electrode for absorbing and recycling solar energy; a semiconductor active layer disposed on the nano rough layer; and a second electrode disposed on the semiconductor active layer.

Regarding the solar battery unit, a material of which at least one of the first and second electrodes is made is a transparent material, and a material of which the other electrode is made is a metallic material. The first electrode has a convoluted surface on which the nano rough layer is disposed.

Regarding the solar battery unit, the nano rough layer comprises a plurality of metallic nanoparticles stacked up, and the metallic nanoparticles is of a dimension ranging between 10 nm and 800 nm.

Regarding the solar battery unit, the nano rough layer comprises a metal membrane and a plurality of metallic nanoparticles disposed on the first electrode and covered with the metal membrane. The metallic nanoparticles are of a dimension ranging between 1 nm and 500 nm.

Regarding the solar battery unit, the first electrode and the second electrode are connected to an external circuit. Once sunlight falls on the first electrode or the second electrode to thereby enter the solar battery unit, the solar battery unit will convert absorbed solar energy into electrical energy. The electrical energy thus generated is available for use by the external circuit. The semiconductor active layer is made of an organic or inorganic material.

The solar battery unit further comprises an electron or hole transport layer disposed between the nano rough layer and the semiconductor active layer or between the semiconductor active layer and the second electrode. The electron or hole transport layer is made of an organic or inorganic material. The solar battery unit further comprises an optical modulation layer disposed between the nano rough layer and the electron or hole transport layer.

The solar battery unit further comprises an electron or hole barrier layer disposed between the nano rough layer and the semiconductor active layer or between the semiconductor active layer and the second electrode. The solar battery unit further comprises an optical modulation layer disposed between the nano rough layer and the electron or hole barrier layer.

The present invention further discloses a solar battery unit, comprising: a substrate; a nano rough structure disposed on the substrate for absorbing and recycling solar energy; a first electrode disposed on the nano rough structure; a semiconductor active layer disposed on the first electrode; and a second electrode disposed on the semiconductor active layer.

Regarding the solar battery unit, the first electrode is made of an elemental metal or an alloy, and the second electrode is made of a transparent material.

The nano rough structure is a convoluted structure formed on the substrate. The difference between the highest peak and the lowest trough of the convoluted structure ranges between 3 nm and 500 nm. The difference in height between a peak and a trough adjacent thereto of the convoluted structure ranges between 1 nm and 500 nm. Alternatively, the nano rough structure comprises a plurality of metallic nanoparticles stacked up, and the metallic nanoparticles are of a dimension ranging between 1 nm and 500 nm.

Regarding the structure, sunlight falls on the second electrode to thereby enter the solar battery unit whereby absorbed solar energy is converted into electrical energy for use by an external circuit connecting the first electrode and the second electrode.

Regarding the solar battery unit, the first electrode is made of a transparent material, and the second electrode is made of an elemental metal or an alloy.

Regarding the structure, the nano rough structure comprises a plurality of metallic nanoparticles stacked up, and a metal membrane is disposed between the first electrode and the semiconductor active layer. The metallic nanoparticles are of a dimension ranging between 1 nm and 500 nm.

Regarding the structure, sunlight falls on the first electrode to thereby enter the solar battery unit whereby absorbed solar energy is converted into electrical energy for use by an external circuit connecting the first electrode and the second electrode.

Regarding the solar battery unit, the semiconductor active layer is made of an organic or inorganic material.

The solar battery unit further comprises an electron or hole transport layer disposed between the first electrode and the semiconductor active layer or between the semiconductor active layer and the second electrode. The electron or hole transport layer is made of an organic or inorganic material.

The solar battery unit further comprises an electron or hole barrier layer disposed between the first electrode and the semiconductor active layer or between the semiconductor active layer and the second electrode.

The solar battery unit further comprises an optical modulation layer disposed between the first electrode and the electron or hole transport layer.

The present invention further discloses a method for fabricating a solar battery unit, comprising the steps of: a method for fabricating a solar battery unit, comprising the steps of: providing a first electrode; forming a nano rough layer on the first electrode; forming a semiconductor active layer on the nano rough layer; and forming a second electrode on the semiconductor active layer. Sunlight falls on the first electrode or the second electrode to thereby enter the solar battery unit whereby absorbed solar energy is converted into electrical energy for use by an external circuit connecting the first electrode and the second electrode.

Regarding the method, one of the first and second electrodes is made of a transparent material, and the other one of the first and second electrodes is made of a metallic material. The surface of the first electrode is a convoluted surface on which the nano rough layer is disposed.

Regarding the method, the nano rough layer comprises a plurality of metallic nanoparticles stacked up, and the metallic nanoparticles are of a dimension ranging between 10 nm and 800 nm.

Regarding the method, the nano rough layer comprises a metal membrane and a plurality of metallic nanoparticles disposed on the first electrode and covered with the metal membrane. The metallic nanoparticles are of a dimension ranging between 1 nm and 500 nm.

The method further comprises connecting the first electrode and the second electrode to an external circuit such that sunlight falls on the first electrode or the second electrode to thereby enter the solar battery unit whereby absorbed solar energy is converted into electrical energy for use by the external circuit, wherein the semiconductor active layer is made of an organic or inorganic material.

The method further comprises forming an electron or hole transport layer between the nano rough layer and the semiconductor active layer or between the semiconductor active layer and the second electrode, wherein the electron or hole transport layer is made of an organic or inorganic material. The method further comprises forming an optical modulation layer between the nano rough layer and the electron or hole transport layer.

The method further comprises forming an electron or hole barrier layer between the nano rough layer and the semiconductor active layer or between the semiconductor active layer and the second electrode. The method further comprises forming an optical modulation layer between the nano rough layer and the electron or hole barrier layer.

The present invention further discloses a method for fabricating a solar battery unit, comprising the steps of: a method for fabricating a solar battery unit, comprising the steps of: providing a substrate; forming a nano rough structure on the substrate; forming a first electrode on the nano rough structure to cover the nano rough structure; forming a semiconductor active layer on the first electrode; and forming a second electrode on the semiconductor active layer. Sunlight falls on the second electrode to thereby enter the solar battery unit whereby absorbed solar energy is converted into electrical energy for use by an external circuit connecting the first electrode and the second electrode.

Regarding the method, the first electrode is made of an elemental metal or an alloy, and the second electrode is made of a transparent material.

Regarding the method, the nano rough structure is a convoluted structure formed on the substrate, and the convoluted structure is formed by a patterning process performed by a chemical or physical means. The difference between a highest peak and a lowest trough of the convoluted structure ranges between 3 nm and 500 nm. The difference in height between a peak and a trough adjacent thereto of the convoluted structure ranges between 1 nm and 500 nm. The nano rough structure comprises a plurality of metallic nanoparticles stacked up, and the metallic nanoparticles are of a dimension ranging between 1 nm and 500 nm.

Regarding the method, the first electrode and the second electrode are connected to an external circuit. Once sunlight falls on the second electrode, the external circuit can use electrical energy generated by the solar battery unit through conversion of energy.

Regarding the method, the first electrode is made of a transparent material, and the second electrode is made of an elemental metal or an alloy.

Regarding the method, the nano rough structure comprises a plurality of metallic nanoparticles stacked up, and a metal membrane is formed between the first electrode and the semiconductor active layer. The metallic nanoparticles are of a dimension ranging between 1 nm and 500 nm.

Regarding the method, the first electrode and the second electrode are connected to an external circuit. Once sunlight falls on the first electrode, the external circuit can use electrical energy generated by the solar battery unit through conversion of energy.

Regarding the method, the semiconductor active layer is made of an organic or inorganic material.

The method further comprises forming an electron or hole transport layer between the first electrode and the semiconductor active layer or between the semiconductor active layer and the second electrode. The electron or hole transport layer is made of an organic or inorganic material.

The method further comprises forming an electron or hole barrier layer between the first electrode and the semiconductor active layer or between the semiconductor active layer and the second electrode.

The method further comprises forming an optical modulation layer between the first electrode and the electron or hole transport layer.

Hence, the present invention teaching forming a nano rough layer on electrodes randomly and by a variable means, or forming a nano rough structure randomly distributed across the substrate by a processing process performed by a variable means, so as to maximize utilization of residual solar energy left behind after absorption of solar energy by the semiconductor active layer and feed back the energy to the semiconductor active layer with a view to optimizing the recycling of solar energy and absorption of solar energy.

Where the solar battery unit is made of an inorganic semiconductor material, the semiconductor active layer of a lesser thickness can work efficiently, because solar energy is effectively recycled in the presence of the rough surfaces of randomly distributed nanoparticles. Also, a desirable thickness of the semiconductor active layer can be controllably attained because of the electron or hole transport layer selectively formed between the nano rough layer and the semiconductor active layer.

In addition, the nano rough layer/structure is conducive to the increase in the contact surface between electrodes and a semiconductor material.

### BRIEF DESCRIPTION OF THE DRAWINGS

FIGS. 1A through 1D are schematic cross-sectional views of a method for fabricating a solar battery unit in a first embodiment according to the present invention;

FIGS. 2A through 2D are schematic cross-sectional views of the method for fabricating a solar battery unit in a second embodiment according to the present invention;

FIGS. 3A through 3D are schematic cross-sectional views of the method for fabricating a solar battery unit in a third embodiment according to the present invention; FIG. 3D′ is a cross-sectional view of another embodiment of the method illustrated with FIG. 3D;

FIGS. 4A through 4D are schematic cross-sectional views of the method for fabricating a solar battery unit in a fourth embodiment according to the present invention;

FIGS. 5A through 5D are schematic cross-sectional views of the method for fabricating a solar battery unit in a fifth embodiment according to the present invention; and

FIGS. 6A through 6D are schematic cross-sectional views of the method for fabricating a solar battery unit in a sixth embodiment according to the present invention; FIG. 6D′ is a cross-sectional view of another embodiment of the method illustrated with FIG. 6D.

### DETAILED DESCRIPTION OF THE EMBODIMENTS

The present invention is herein illustrated with specific embodiments, so that one skilled in the pertinent art can easily understand other advantages and effects of the present invention from the disclosure of the invention.

### First Embodiment

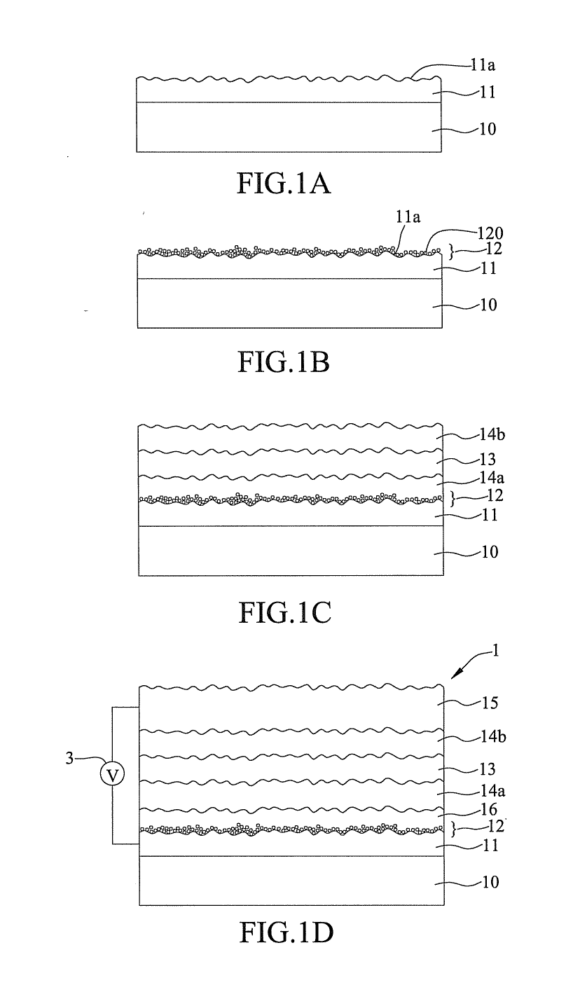

Referring to FIGS. 1A through 1D, there are shown schematic cross-sectional views of a method for fabricating a solar battery unit 1 in a first embodiment according to the present invention.

Referring to FIG. 1A, a first electrode 11 is provided, and the first electrode 11 is disposed on a substrate 10. The material of which the substrate 10 is made is a transparent material, paper, glass, a polymeric material, or a metallic material.

In this embodiment, the first electrode 11 is formed by applying a metallic material to the substrate 10, using sputtering, evaporation, spin coating, immersion, spraying, drying after dripping, organic metal chemical vapor deposition (MOCVD), electroplating, or a chemical reaction. The metallic material is Al, Au, Cu, Ag, Cr, Pt, Co, Ni, or Ti. In this embodiment, the material of which the first electrode 11 is made can also be a non-metallic material.

In this embodiment, the first electrode 11 has a convoluted surface 11a. The convoluted surface 11a is formed by creating randomly distributed nano-convolution on the surface of the first electrode 11 according to different fabrication parameters, or by creating a randomly distributed nanoscale convoluted rough surface on the first electrode 11 by means of dry-etching after plating. The extent of convolution of the first electrode 11 is adjustably set to between 1 nm and 500 nm according to different fabrication parameters.

Referring to FIG. 1B, a nano rough layer 12 is formed on the convoluted surface 11a of the first electrode 11. In this embodiment, the nano rough layer 12 comprises a plurality of metallic nanoparticles 120 stacked up.

The plurality of metallic nanoparticles 120 is stacked up by sputtering, evaporation, spin coating, immersion, spraying, drying after dripping, organic metal chemical vapor deposition (MOCVD), electroplating, or a chemical reaction (such as Tollens' test, also known as silver-mirror test) and thereby randomly distributed across the first electrode 11. The metallic nanoparticles 120 is made of Al, Au, Cu, Ag, Cr, Pt, Co, Ni, or Ti. The dimensions of the metallic nanoparticles 120 are controllably set to between 10 nm and 800 nm by adjustment and processing according to different fabrication parameters, so as to alter the absorption wavelength of the metallic nanoparticles 120. The thickness of the nano rough layer 12 is subject to changes as needed, so as to enhance the performance thereof.

The nano rough layer 12 of the present invention is effective in increasing particle dimensions and variety, enhancing surface roughness, and enhancing utilization of spectral energy.

Referring to FIG. 1C, a semiconductor active layer 13 is formed on the nano rough layer 12, and the semiconductor active layer 13 is formed from an organic or inorganic material. The semiconductor active layer 13 and the metallic nanoparticles 120 are equal in absorption wavelength.

In an embodiment of the present invention, an electron or hole transport layer 14a is selectively formed between the nano rough layer 12 and the semiconductor active layer 13 so as to enhance performance thereof. Alternatively, an electron or hole transport layer 14b is selectively formed on the semiconductor active layer 13 to allow an electrode layer to be subsequently disposed thereon, so as to enhance performance thereof. In this embodiment, two said electron or hole transport layers 14a, 14b are disposed in the solar battery unit 1.

Referring to FIG. 1D, a second electrode 15 is formed on the electron or hole transport layer 14b above the semiconductor active layer 13. The material of which the second electrode 15 is made is a transparent material. The first electrode 11 and the second electrode 15 are connected to an external circuit 3. Once sunlight falls on the second electrode 15 to thereby enter the solar battery unit 1, the solar battery unit 1 will convert absorbed solar energy into electrical energy. The external circuit 3 is configured to use the electrical energy thus generated.

In this embodiment, the material of which the first electrode 11 is made is a transparent material, and both the first electrode 11 and the second electrode 15 are made of a transparent material.

The electron or hole transport layers 14a, 14b of the solar battery unit 1 are replaceable by an electron or hole barrier layer (not shown). Also, it is feasible to form an optical modulation layer 16 (an optical spacer layer) between the nano rough layer 12 and the electron or hole transport layer 14a (or an electron or hole barrier layer), so as to enhance utilization of spectral energy, as shown in FIG. 1D.

### Second Embodiment

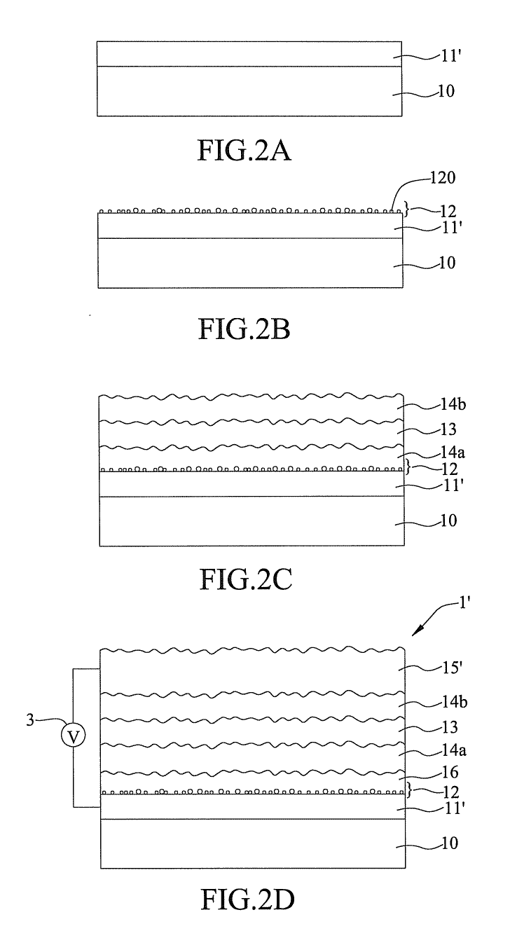

Referring to FIGS. 2A through 2D, there are shown schematic cross-sectional views of the method for fabricating a solar battery unit 1′ in a second embodiment according to the present invention. The difference between the second embodiment and the first embodiment is that, in the second embodiment, the first electrode 11′ and the second electrode 15′ are made of different material.

Referring to FIG. 2A, the first electrode 11′ is provided, and the first electrode 11′ is disposed on the substrate 10. In this embodiment, the material of which the first electrode 11′ is made is a transparent material, and thus the substrate 10 is also made of a transparent material. The first electrode 11′ has a flat surface.

Referring to FIG. 2B, the nano rough layer 12 is formed on the first electrode 11′, and the nano rough layer 12 comprises a plurality of metallic nanoparticles 120 stacked up. The plurality of metallic nanoparticles 120 is stacked up by spin coating, immersion, spraying, drying after dripping, organic metal chemical vapor deposition (MOCVD), electroplating, or a chemical reaction (such as Tollens' test, also known as silver-minor test). As a result, the metallic nanoparticles 120 are randomly distributed across the first electrode 11′. The dimensions of the metallic nanoparticles 120 are controlled by adjustment and processing according to different fabrication parameters.

Referring to FIG. 2C, the electron or hole transport layer 14a, the semiconductor active layer 13, and the electron or hole transport layer 14b are formed on the nano rough layer 12 in a bottom-to-top order.

Referring to FIG. 2D, the second electrode 15′ is formed on the electron or hole transport layer 14b above the semiconductor active layer 13. The material from the second electrode 15′ is made is a metallic material. The first electrode 11′ and the second electrode 15′ are connected to the external circuit 3. Once sunlight falls on the first electrode 11′ to thereby enter the solar battery unit 1′, the solar battery unit 1′ will convert absorbed solar energy into electrical energy. The external circuit 3 is configured to use the electrical energy thus generated.

In this embodiment, the material of which the second electrode 15′ is made is a non-metallic material. Likewise, the material of which the second electrode 15′ is made is a transparent material, and thus both the first electrode 11′ and the second electrode 15′ are made of a transparent material.

The electron or hole transport layers 14a, 14b of the solar battery unit 1′ are replaceable by an electron or hole barrier layer (not shown). Also, it is feasible to form an optical modulation layer 16 between the nano rough layer 12 and the electron or hole transport layer 14a (or an electron or hole barrier layer), so as to enhance utilization of spectral energy, as shown in FIG. 2D.

### Third Embodiment

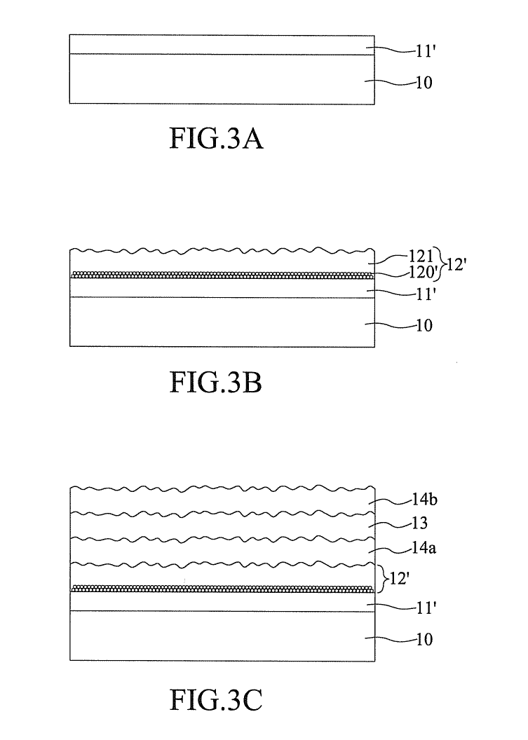

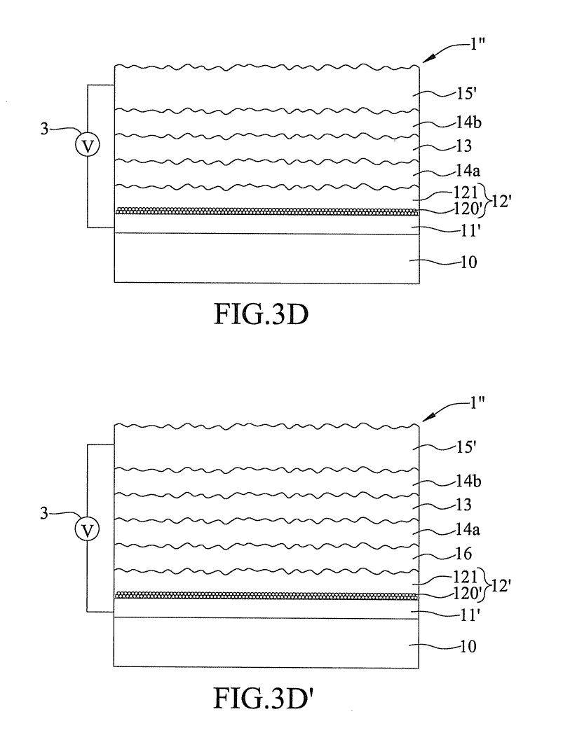

Referring to FIGS. 3A through 3D, there are shown schematic cross-sectional views of the method for fabricating a solar battery unit 1″ in a third embodiment according to the present invention. The difference between the third embodiment and the second embodiment is that, in the third embodiment, a nano rough layer 12′ takes on a new structure.

Referring to FIG. 3A, the first electrode 11′ is provided, and the first electrode 11′ is disposed on the substrate 10. The material of which the first electrode 11′ and the substrate 10 are made is a transparent material.

Referring to FIG. 3B, the nano rough layer 12′ is formed on the first electrode 11′, and the nano rough layer 12′ comprises a metal membrane 121 and a plurality of metallic nanoparticles 120′ disposed on the first electrode 11′ and covered with the metal membrane 121.

There is no limitation on the material of which the metallic nanoparticles 120′ are made, though the material is preferably a transparent material. The metallic nanoparticles 120′ are formed on the first electrode 11′ by sputtering, evaporation, spin coating, immersion, spraying, drying after dripping, organic metal chemical vapor deposition (MOCVD), electroplating, or a chemical reaction. As a result, the metallic nanoparticles 120 are randomly distributed across the first electrode 11′. The dimensions of the metallic nanoparticles 120′ are controllably set to between 1 and 500 nm by adjustment and processing according to different fabrication parameters, so as to alter the absorption wavelength of the metallic nanoparticles 120′.

The metal membrane 121 is made of Al, Au, Cu, Ag, Cr, Pt, Co, Ni, or Ti. The metallic nanoparticles 120′ are covered with the metal membrane 121 by sputtering, evaporation, spin coating, immersion, spraying, drying after dripping, organic metal chemical vapor deposition (MOCVD), electroplating, or a chemical reaction.

The nano rough layer 12′ of the present invention is effective in increasing particle dimensions and variety, enhancing surface roughness, and augmenting utilization of spectral energy.

Referring to FIG. 3C, the electron or hole transport layer 14a, the semiconductor active layer 13, and the electron or hole transport layer 14b are formed on the nano rough layer 12′ in a bottom-to-top order. The semiconductor active layer 13 and the metallic nanoparticles 120′ are equal in absorption wavelength.

Referring to FIG. 3D, the second electrode 15′ is formed on the electron or hole transport layer 14b above the semiconductor active layer 13. The material of which the second electrode 15′ is made is a metallic material. The first electrode 11′ and the second electrode 15′ are connected to the external circuit 3. Once sunlight falls on the first electrode 11′ to thereby enter the solar battery unit 1″, the solar battery unit 1″ will convert absorbed solar energy into electrical energy. The external circuit 3 is configured to use the electrical energy thus generated.

In this embodiment, the electron or hole transport layers 14a, 14b of the solar battery unit 1″ are replaceable by an electron or hole barrier layer (not shown). Also, it is feasible to form the optical modulation layer 16 between the nano rough layer 12′ and the electron or hole transport layer 14a (or an electron or hole barrier layer), so as to enhance utilization of spectral energy, as shown in FIG. 3D′.

In the aforesaid three embodiments, the present invention further provides the solar battery unit 1, 1′, 1″ comprising: the first electrodes 11, 11′; the nano rough layers 12, 12′ formed on the first electrodes 11, 11′; the semiconductor active layer 13 formed above the nano rough layers 12, 12′; and the second electrodes 15, 15′ formed above the semiconductor active layer 13.

One of the first and second electrodes 11, 11′, 15, 15′ is made of a transparent material. The other one of the first and second electrodes 11, 11′, 15, 15′ is made of a metallic material. The first electrodes 11, 11′ and the second electrodes 15, 15′ are connected to an external circuit. Once sunlight falls on the first electrode 11′ or the second electrode 15, absorbed solar energy will be converted into electrical energy. The external circuit is configured to use the electrical energy thus generated. The first electrodes 11, 11′ have the convoluted surface 11a on which the nano rough layers 12, 12′ are disposed.

The material of which the semiconductor active layer 13 is made is an organic or inorganic material. The nano rough layer 12 comprises a plurality of metallic nanoparticles 120 stacked up. The metallic nanoparticles 120 are of a dimension ranging between 10 nm and 800 nm. Alternatively, the nano rough layer 12′ comprises the metal membrane 121 and the plurality of metallic nanoparticles 120′ disposed on the first electrode 11′ and covered with the metal membrane 121. The metallic nanoparticles 120′ are of a dimension ranging between 1 nm and 500 nm.

The solar battery unit 1, 1′, 1″ further comprises the electron or hole transport layers 14a, 14b disposed between the nano rough layers 12, 12′ and the semiconductor active layer 13 and between the semiconductor active layer 13 and the second electrodes 15, 15′, respectively. The material of which the electron or hole transport layers 14a, 14b are made is an organic or inorganic material.

### Fourth Embodiment

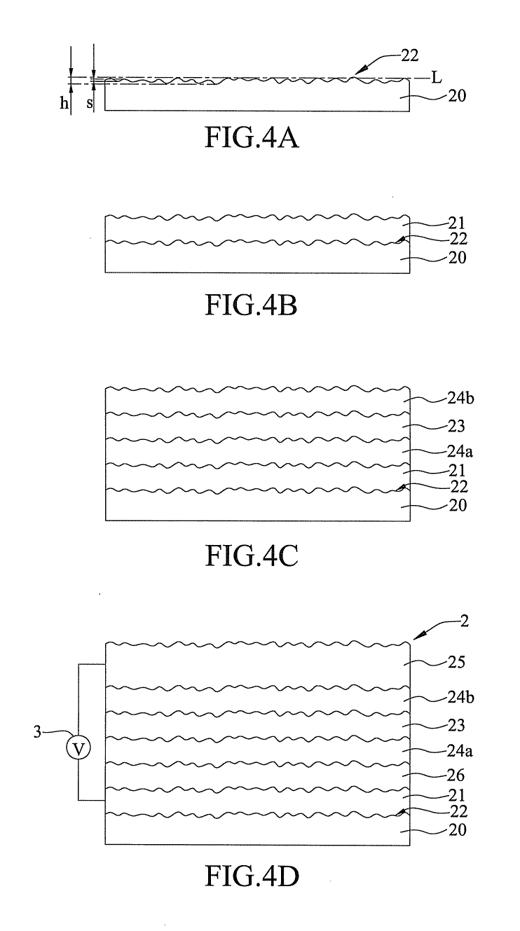

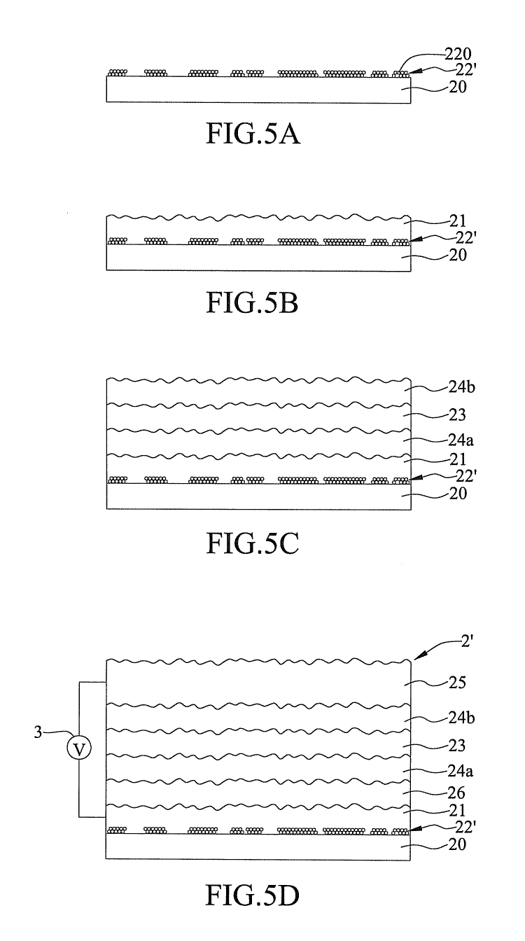

Referring to FIGS. 4A through 4D, there are shown schematic cross-sectional views of the method for fabricating a solar battery unit 2 in a fourth embodiment according to the present invention.

Referring to FIG. 4A, a substrate 20 is prepared, and a nano rough structure 22 is disposed on the substrate 20. The material of which the substrate 20 is made is paper, glass, a polymeric material, or a metallic material. In this embodiment, the nano rough structure 22 is a convoluted structure formed on the substrate 20.

The nano rough structure 22 is formed by a patterning process performed by a chemical or physical means, such as molding, dry-etching, wet-etching, mechanical polishing, photolithography, scanning-beam lithography, or printing, so as to form on the substrate 20 a convoluted structure characterized by randomly distributed nanoscale roughness. The maximum peak-to-trough height h of the convoluted structure ranges between 3 nm and 500 nm, which is the difference between the highest peak and the lowest trough on the substrate 20. The reference surface L shown in FIG. 4A is the original surface of the substrate 20. The contiguous peak-to-trough height s of the convoluted structure ranges between 1 nm and 500 nm, which is the difference in height between a peak and a trough adjacent thereto on the substrate 20.

The nano rough structure 22 of the present invention is effective in increasing particle dimensions and variety, enhancing surface roughness, and augmenting utilization of spectral energy.

Referring to FIG. 4B, after the substrate 20 is rinsed and dried, a first electrode 21 is formed on the nano rough structure 22 to thereby cover the nano rough structure 22. The first electrode 21 is formed by applying an elemental metal or an alloy to the substrate 20 by sputtering, evaporation, spin coating, immersion, spraying, drying after dripping, organic metal chemical vapor deposition (MOCVD), electroplating, or a chemical reaction. The first electrode 21 is made of Al, Au, Cu, Ag, Cr, Pt, Co, Ni, or Ti.

Randomly distributed nano-convolution is formed on the surface of the first electrode 21 according to different fabrication parameters. Alternatively, a randomly distributed nanoscale convoluted rough surface is formed on the first electrode 21 by means of dry-etching after plating. The extent of convolution of the first electrode 21 is adjustably set to between 1 nm and 500 nm according to different fabrication parameters.

The thickness of the first electrode 21 is subject to changes as needed.

Referring to FIG. 4C, a semiconductor active layer 23 is formed on the first electrode 21, and the material of which the semiconductor active layer 23 is made is an organic or inorganic material.

In an embodiment of the present invention, an electron or hole transport layer 24a is selectively formed between the first electrode 21 and the semiconductor active layer 23 so as to enhance performance thereof. Alternatively, an electron or hole transport layer 24b is selectively formed on the semiconductor active layer 23 to allow an electrode layer to be subsequently disposed thereon, so as to enhance performance thereof. In this embodiment, two said electron or hole transport layers 24a, 24b are disposed in the solar battery unit 2.

Referring to FIG. 4D, a second electrode 25 is formed on the electron or hole transport layer 24b above the semiconductor active layer 23. The material of which the second electrode 25 is made is a transparent material. The first electrode 21 and the second electrode 25 are connected to the external circuit 3. Once sunlight falls on the second electrode 25 to thereby enter the solar battery unit 2, the solar battery unit 2 will convert absorbed solar energy into electrical energy. The external circuit 3 is configured to use the electrical energy thus generated.

In this embodiment, the electron or hole transport layers 24a, 24b of the solar battery unit 2 are replaceable by an electron or hole barrier layer (not shown). Also, it is feasible to form an optical modulation layer 26 between the first electrode 21 and the electron or hole transport layer 24a (or an electron or hole barrier layer), so as to enhance utilization of spectral energy, as shown in FIG. 4D.

### Fifth Embodiment

Referring to FIGS. 5A through 5D, there are shown schematic cross-sectional views of the method for fabricating a solar battery unit 2′ in a fifth embodiment according to the present invention. The difference between the fifth embodiment and the fourth embodiment is that the nano rough structure 22′ in the fifth embodiment assumes a new structure.

Referring to FIG. 5A, the substrate 20 is provided, and the nano rough structure 22′ is formed on the substrate 20. In this embodiment, the nano rough structure 22′ comprises a plurality of metallic nanoparticles 220 stacked up.

There is no limitation upon the material of which the metallic nanoparticles 220 are made, though the material is preferably a transparent material. The metallic nanoparticles 220 are stacked up by sputtering, evaporation, spin coating, immersion, spraying, drying after dripping, organic metal chemical vapor deposition (MOCVD), electroplating, or a chemical reaction, before being randomly distributed across the substrate 20. The metallic nanoparticles 220 are processed or adjusted by different fabrication parameters so as for the dimensions of the metallic nanoparticles 220 to range between 1 nm and 500 nm with a view to varying the absorption wavelength of the metallic nanoparticles 220.

The nano rough structure 22′ of the present invention is effective in increasing particle dimensions and variety, enhancing surface roughness, and augmenting utilization of spectral energy.

Referring to FIG. 5B, the first electrode 21 is formed on the nano rough structure 22′ to thereby cover the nano rough structure 22′.

Referring to FIG. 5C, the electron or hole transport layer 24a, the semiconductor active layer 23, and the electron or hole transport layer 24b are formed on the first electrode 21 in a bottom-to-top order.

Referring to FIG. 5D, the second electrode 25 is formed on the electron or hole transport layer 24b above the semiconductor active layer 23, and both the first electrode 21 and the second electrode 25 are connected to the external circuit 3. Once sunlight falls on the second electrode 25 to thereby enter the solar battery unit 2′, the solar battery unit 2′ will convert absorbed solar energy into electrical energy. The electrical energy thus generated is available for use by the external circuit 3.

In this embodiment, the electron or hole transport layers 24a, 24b of the solar battery unit 2′ are replaceable by an electron or hole barrier layer (not shown). Also, it is feasible to form the optical modulation layer 26 between the first electrode 21 and the electron or hole transport layer 24a (or an electron or hole barrier layer), so as to enhance utilization of spectral energy, as shown in FIG. 5D.

### Sixth Embodiment

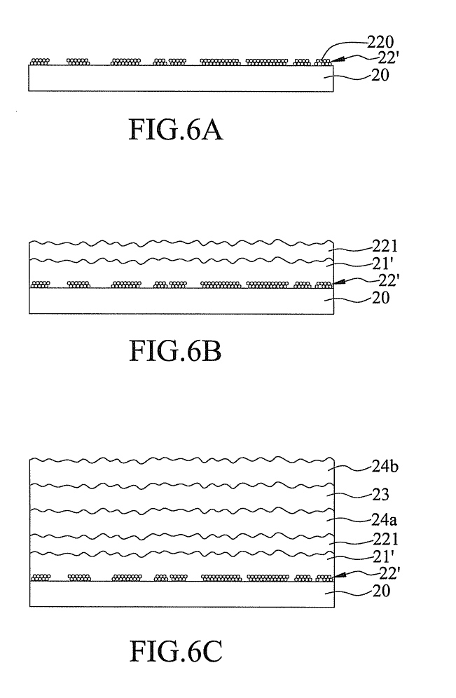

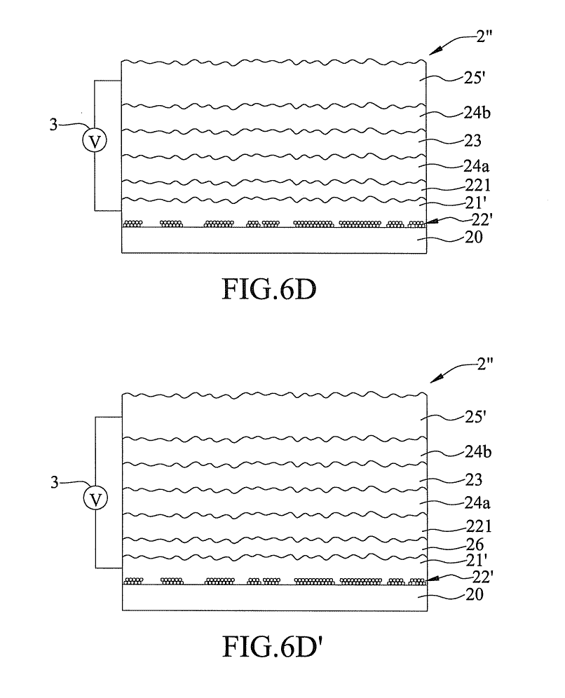

Referring to FIGS. 6A through 6D, there are shown schematic cross-sectional views of the method for fabricating a solar battery unit 2″ in a sixth embodiment according to the present invention. The difference between the sixth embodiment and the fifth embodiment lies in the material of which the first and second electrodes 21′, 25′ are made and a metal membrane 221 in the sixth embodiment.

Referring to FIG. 6A, the substrate 20 is provided, a nano rough structure 22′ is formed on the substrate 20. The nano rough structure 22′ comprises a plurality of metallic nanoparticles 220 stacked up.

The nano rough structure 22′ of the present invention is effective in increasing particle dimensions and variety, enhancing surface roughness, and augmenting utilization of spectral energy.

Referring to FIG. 6B, a first electrode 21′ is formed on the nano rough structure 22′ to cover the nano rough structure 22′, and then the metal membrane 221 is formed on the first electrode 21′. The material of which the first electrode 21′ is made is a transparent material.

The metal membrane 221 is made of Al, Au, Cu, Ag, Cr, Pt, Co, Ni, or Ti. The metallic nanoparticles 120′ are covered with the metal membrane 221 by sputtering, evaporation, spin coating, immersion, spraying, drying after dripping, organic metal chemical vapor deposition (MOCVD), electroplating, or a chemical reaction.

Referring to FIG. 6C, the electron or hole transport layer 24a, the semiconductor active layer 23, and the electron or hole transport layer 24b are formed on the metal membrane 221 in a bottom-to-top order.

Referring to FIG. 6D, the second electrode 25′ is formed on the electron or hole transport layer 24b above the semiconductor active layer 23. The material of which the second electrode 25′ is made is an elemental metal or an alloy. The elemental metal is Al, Au, Cu, Ag, Cr, Pt, Co, Ni, or Ti. The first electrode 21′ and the second electrode 25′ are connected to the external circuit 3. Once sunlight falls on the substrate 20 and the first electrode 21′ to thereby enter the solar battery unit 2″, the solar battery unit 2″ will convert absorbed solar energy into electrical energy. The external circuit 3 can use the electrical energy thus generated.

In this embodiment, the electron or hole transport layers 24a, 24b of the solar battery unit 2″ are replaceable by an electron or hole barrier layer (not shown). Also, it is feasible to form the optical modulation layer 26 between the first electrode 21′ and the metal membrane 221, so as to enhance utilization of spectral energy, as shown in FIG. 6D′.

In the aforesaid three embodiments, the present invention further provides the solar battery unit 2, 2′, 2″ comprising: the substrate 20; the nano rough structure 22, 22′ formed on the substrate 20; the first electrode 21, 21′ formed on the nano rough structures 22, 22′; the semiconductor active layer 23 formed on the first electrodes 21, 21′; and the second electrodes 25, 25′ formed on the semiconductor active layer 23.

If the first electrode 21 is made of an elemental metal or an alloy, the second electrode 25 will be made of a transparent material. The nano rough structure 22 is a convoluted structure formed on the substrate 20. The maximum peak-to-trough height h of the convoluted structure ranges between 3 nm and 500 nm. The contiguous peak-to-trough height s of the convoluted structure ranges between 1 nm and 500 nm. Alternatively, the nano rough structure 22′ comprises a plurality of metallic nanoparticles 220 stacked up, and the metallic nanoparticles 220 are of a dimension ranging between 1 nm and 500 nm. The first electrode 21 and the second electrode 25 are connected to the external circuit 3. Once sunlight falls on the second electrode 25, the external circuit 3 will use electrical energy generated.

If the first electrode 21′ is made of a transparent material, the second electrode 25′ will be made of an elemental metal or an alloy. The nano rough structure 22′ comprises a plurality of metallic nanoparticles 220 stacked up. The metal membrane 221 is formed between the first electrode 21′ and the semiconductor active layer 23. The metallic nanoparticles 220 are of a dimension ranging between 1 nm and 500 nm. The first electrode 21′ and the second electrode 25′ are connected to the external circuit 3. Once sunlight falls on the substrate 20 and the first electrode 21′, the external circuit 3 will use electrical energy generated.

The material of which the semiconductor active layer 23 is made is an organic or inorganic material. The solar battery unit 2, 2′, 2″ further comprises the electron or hole transport layers 24a, 24b disposed between the first electrode 21, 21′ and the semiconductor active layer 23 and between the semiconductor active layer 23 and the second electrodes 25, 25′. The electron or hole transport layers 24a, 24b are made of an organic or inorganic material.

In conclusion, the present invention teaches forming a nano rough layer on electrodes randomly or forming a randomly distributed nano rough structure by processing the substrate using a variable means, so as to maximize utilization of residual solar energy left behind after absorption of solar energy by the semiconductor active layer and then feed back the energy to the semiconductor active layer with a view to optimizing the recycling of solar energy and absorption of solar energy.

Where the solar battery unit is made of an inorganic semiconductor material, the semiconductor active layer of a lesser thickness can work efficiently, because solar energy is effectively recycled in the presence of the rough surfaces of randomly distributed nanoparticles. Also, a desirable thickness of the semiconductor active layer can be controllably attained because of the electron or hole transport layer selectively formed between the nano rough layer and the semiconductor active layer.

In addition, the nano rough layer/structure is conducive to the increase in the contact surface between electrodes and a semiconductor material.

The foregoing descriptions of the detailed embodiments are provided to illustrate and disclose the features and functions of the present invention and are not intended to be restrictive of the scope of the present invention. It should be understood by those in the art that many modifications and variations can be made according to the spirit and principle in the disclosure of the present invention and still fall within the scope of the invention as set forth in the appended claims.

1. A solar battery unit, comprising:
a first electrode;
a nano rough layer disposed on the first electrode for absorbing and recycling solar energy;
a semiconductor active layer disposed on the nano rough layer; and
a second electrode disposed on the semiconductor active layer.

2. The solar battery unit of claim 1, wherein at least one of the first and second electrodes is made of a transparent material, and the other electrode is made of a metallic material.

3. The solar battery unit of claim 1, wherein at least one of the first and second electrodes is made of a transparent material.

4. The solar battery unit of claim 1, wherein the first electrode has a convoluted surface on which the nano rough layer is disposed.

5. The solar battery unit of claim 1, wherein the nano rough layer comprises a plurality of metallic nanoparticles stacked up, the metallic nanoparticles being of a dimension ranging between 10 nm and 800 nm.

6. The solar battery unit of claim 1, wherein the nano rough layer comprises a plurality of metallic nanoparticles covered with a metal membrane and disposed on the first electrode, the plurality of metallic nanoparticles being of a dimension ranging between 1 nm and 500 nm.

7. The solar battery unit of claim 1, wherein sunlight falls on the first electrode or the second electrode to thereby enter the solar battery unit whereby absorbed solar energy is converted into electrical energy for use by an external circuit connecting the first electrode and the second electrode.

8. The solar battery unit of claim 1, wherein the semiconductor active layer is made of an organic or inorganic material.

9. The solar battery unit of claim 1, further comprising an electron or hole transport layer disposed between the nano rough layer and the semiconductor active layer.

10. The solar battery unit of claim 9, further comprising an optical modulation layer disposed between the nano rough layer and the electron or hole transport layer.

11. The solar battery unit of claim 1, further comprising an electron or hole transport layer disposed between the semiconductor active layer and the second electrode.

12. The solar battery unit of claim 1, further comprising an electron or hole barrier layer disposed between the nano rough layer and the semiconductor active layer.

13. The solar battery unit of claim 12, further comprising an optical modulation layer disposed between the nano rough layer and the electron or hole barrier layer.

14. The solar battery unit of claim 1, further comprising an electron or hole barrier layer disposed between the semiconductor active layer and the second electrode.

15. A solar battery unit, comprising:
a substrate;
a nano rough structure disposed on the substrate for absorbing and recycling solar energy;
a first electrode disposed on the nano rough structure;
a semiconductor active layer disposed on the first electrode; and
a second electrode disposed on the semiconductor active layer.

16. The solar battery unit of claim 15, wherein the first electrode is made of an elemental metal or an alloy, and the second electrode is made of a transparent material.

17. The solar battery unit of claim 16, wherein the nano rough structure is a convoluted structure formed on the substrate.

18. The solar battery unit of claim 17, wherein a difference between a highest peak and a lowest trough of the convoluted structure ranges between 3 nm and 500 nm.

19. The solar battery unit of claim 17, wherein a difference in height between a peak and a trough adjacent thereto of the convoluted structure ranges between 1 nm and 500 nm.

20. The solar battery unit of claim 16, wherein the nano rough structure comprises a plurality of metallic nanoparticles stacked up, the metallic nanoparticles being of a dimension ranging between 1 nm and 500 nm.

21. The solar battery unit of claim 16, wherein sunlight falls on the second electrode to thereby enter the solar battery unit whereby absorbed solar energy is converted into electrical energy for use by an external circuit connecting the first electrode and the second electrode.

22. The solar battery unit of claim 15, wherein the first electrode is made of a transparent material, and the second electrode is made of an elemental metal or an alloy.

23. The solar battery unit of claim 22, wherein the nano rough structure comprises a plurality of metallic nanoparticles stacked up, and a metal membrane is formed between the first electrode and the semiconductor active layer, the metallic nanoparticles being of a dimension ranging between 1 nm and 500 nm.

24. The solar battery unit of claim 22, wherein the first electrode and the second electrode are connected to the external circuit for using electrical energy generated by transformation taking place in the solar battery unit after sunlight pass through the first electrode.

25. The solar battery unit of claim 15, further comprising an electron or hole transport layer disposed between the first electrode and the semiconductor active layer.

26. The solar battery unit of claim 15, further comprising an electron or hole transport layer disposed between the semiconductor active layer and the second electrode.

27. The solar battery unit of claim 26, further comprising an optical modulation layer disposed between the first electrode and the electron or hole transport layer.

28. The solar battery unit of claim 15, further comprising an electron or hole barrier layer disposed between the first electrode and the semiconductor active layer.

29. The solar battery unit of claim 15, further comprising an electron or hole barrier layer disposed between the semiconductor active layer and the second electrode.

30. A method for fabricating a solar battery unit, comprising the steps of:
providing a first electrode;
forming a nano rough layer on the first electrode;
forming a semiconductor active layer on the nano rough layer; and
forming a second electrode on the semiconductor active layer.

31. The method of claim 30, wherein one of the first and second electrodes is made of a transparent material, and the other one of the first and second electrodes is made of a metallic material.

32. The method of claim 30, wherein at least one of the first and second electrodes is made of a transparent material.

33. The method of claim 30, wherein the first electrode has a convoluted surface on which the nano rough layer is disposed.

34. The method of claim 30, wherein the nano rough layer comprises a plurality of metallic nanoparticles stacked up, the metallic nanoparticles being of a dimension ranging between 10 nm and 800 nm.

35. The method of claim 30, wherein the nano rough layer comprises the metal membrane and a plurality of metallic nanoparticles disposed on the first electrode and covered with the metal membrane, the metallic nanoparticles being of a dimension ranging between 1 nm and 500 nm.

36. The method of claim 30, wherein sunlight falls on the first electrode or the second electrode to thereby enter the solar battery unit whereby absorbed solar energy is converted into electrical energy for use by an external circuit connecting the first electrode and the second electrode.

37. The method of claim 30, further comprising forming an electron or hole transport layer between the nano rough layer and the semiconductor active layer.

38. The method of claim 37, further comprising forming an optical modulation layer between the nano rough layer and the electron or hole transport layer.

39. The method of claim 30, further comprising forming an electron or hole transport layer between the semiconductor active layer and the second electrode.

40. The method of claim 30, further comprising forming an electron or hole barrier layer between the nano rough layer and the semiconductor active layer.

41. The method of claim 37, further comprising forming an optical modulation layer between the nano rough layer and the electron or hole barrier layer.

42. The method of claim 30, further comprising forming an electron or hole barrier layer between the semiconductor active layer and the second electrode.

43. A method for fabricating a solar battery unit, comprising the steps of:
providing a substrate;
foaming a nano rough structure on the substrate;
forming a first electrode on the nano rough structure to cover the nano rough structure;
forming a semiconductor active layer on the first electrode; and
forming a second electrode on the semiconductor active layer.

44. The method of claim 43, wherein the first electrode is made of an elemental metal or an alloy, and the second electrode is made of a transparent material.

45. The method of claim 44, wherein the nano rough structure is a convoluted structure formed on the substrate.

46. The method of claim 45, wherein the convoluted structure is formed by a patterning process performed by a chemical or physical means.

47. The method of claim 45, wherein a difference between a highest peak and a lowest trough of the convoluted structure ranges between 3 nm and 500 nm.

48. The method of claim 45, wherein a difference in height between a peak and a trough adjacent thereto of the convoluted structure ranges between 1 nm and 500 nm.

49. The method of claim 44, wherein the nano rough structure comprises a plurality of metallic nanoparticles stacked up, the metallic nanoparticles being of a dimension ranging between 1 nm and 500 nm.

50. The method of claim 44, wherein sunlight falls on the second electrode to thereby enter the solar battery unit whereby absorbed solar energy is converted into electrical energy for use by an external circuit connecting the first electrode and the second electrode.

51. The method of claim 43, wherein the first electrode is made of a transparent material, and the second electrode is made of an elemental metal or an alloy.

52. The method of claim 51, wherein the nano rough structure comprises a plurality of metallic nanoparticles stacked up, and a metal membrane is formed between and the first electrode and the semiconductor active layer.

53. The method of claim 52, wherein the metallic nanoparticles are of a dimension ranging between 1 nm and 500 nm.

54. The method of claim 51, wherein sunlight falls on the first electrode to thereby enter the solar battery unit whereby absorbed solar energy is converted into electrical energy for use by an external circuit connecting the first electrode and the second electrode.

55. The method of claim 43, further comprising forming an electron or hole transport layer between the first electrode and the semiconductor active layer.

56. The method of claim 43, further comprising forming an electron or hole transport layer between the semiconductor active layer and the second electrode.

57. The method of claim 55, wherein the electron or hole transport layer is made of an organic or inorganic material.

58. The method of claim 55, further comprising forming an optical modulation layer between the first electrode and the electron or hole transport layer.

59. The method of claim 43, further comprising forming an electron or hole barrier layer between the first electrode and the semiconductor active layer.

60. The method of claim 43, further comprising forming an electron or hole barrier layer between the semiconductor active layer and the second electrode.

61. The method of claim 56, wherein the electron or hole transport layer is made of an organic or inorganic material.
